(19) United States
(12) Patent Application Publication
(10) Pub. No.: US 2008/0157273 A1
(43) Pub. Date: Jul. 3, 2008

(54) INTEGRATED ELECTRONIC CIRCUIT CHIP COMPRISING AN INDUCTOR

(75) Inventors: Jean-Christophe Giraudin, Bernin (FR); Philippe Delpech, Meylan (FR); Jacky Seiller, Veurey Voroize (FR)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS SA, Montrouge (FR)

(21) Appl. No.: 11/965,127

(22) Filed: Dec. 27, 2007

(30) Foreign Application Priority Data
Jan. 3, 2007 (FR) 07 00026

(51) Int. Cl. H01L 29/00; H01L 21/02

(52) U.S. Cl. 257/531; 438/381; 257/E29.001; 257/E21.022

(57) ABSTRACT

An integrated electronic circuit chip having an inductor placed above a protective layer for the metallization levels of the chip, the inductor having a thickness in a direction perpendicular to a surface of a substrate of the chip. The inductor has a reduced electrical resistance and a high quality factor. In addition, an inductor is realized at the same time as the pads for connecting the chip to a supporting board using flip-chip technology.

### BACKGROUND

1. Technical Field

The present disclosure relates to an integrated electronic circuit chip that includes an inductor formed above a protective layer, as well as a process for implementing such a chip, and to an electronic circuit assembly incorporating such a chip.

2. Description of the Related Art

Many electronic circuits, such as mobile telephone receivers, filters, and oscillators, contain an induction coil or inductor. Some of these applications require that the inductor have a high quality factor and a high electrical conduction capacity. In addition, to reduce the cost of the electronic circuit, it is necessary to decrease the dimensions of the inductor and to simplify the circuit implementation process.

In a first type of electronic circuit with inductors, called a System on Chip or SoC, the inductors are incorporated into the integrated circuit. In other words, for each circuit, the inductor is integrated into the chip, which also includes transistors. In this case, the connections that electrically connect the inductor to other electronic components of the chip have very small dimensions. These connections then present parasitic resistances as well as coefficients of mutual inductance that are very low. The Joule heating that occurs during operation of the circuit is therefore reduced, and the inductance value is precisely defined. However, capacitive interactions appear between the inductor and other components of the chip because of the proximity of all components within the chip. Such interactions are particularly problematic for applications in the radio frequency (RF) domain.

In SoC circuits, the inductor is formed by a spiraling pathway that is placed in a metallization level of the chip, above the surface of a chip substrate. Such a level contains electrical connections that are pathways or vias, connecting electronic components integrated into the chip. The thickness of the inductor is then limited by that of the corresponding metallization level. It is on the order of 1 to 4 μm (micrometers). Because of this thinness, the current-carrying capacity of the inductor is limited. In addition, the electrical resistance of the inductor is too high for some circuit applications.

Also, the inductor has an internal terminal, which corresponds to the central end of the spiral, and an external terminal, at the opposite end of the spiral. Thus it is necessary to connect the internal terminal electrically in a direction perpendicular to the metallization level, because of the inductor turns that encircle the internal terminal. This requires a special arrangement of the metallization level located just above or below the level of the inductor, which results in an increased complexity of the circuit chip. Often, a pathway must also be placed in this metallization level just above or below the level of the inductor, in a direction radial to the spiral, in order to connect the internal terminal of the inductor by passing below or above the turns. Because of this radial pathway, the quality factor of the inductor is generally less than 30. Such a value is not compatible with many electronic circuit applications.

In a second type of electronic circuit with inductors, called a System In Package or SiP, the inductors are incorporated into a package that contains the chip of the integrated electronic circuit. In particular, the inductors can be implemented in the form of spiraling conductive pathways printed onto a supporting board for the chip, commonly called the laminate. The chip of the integrated electronic circuit is connected to the supporting board using one of the known connection techniques, such as wire bonding. Another technique, called the flip-chip technique, consists of inverting the chip above the supporting board and creating solder bumps between aligned connection pads arranged to face each other on the chip and on the supporting board. In this case, however, the design rules imposed for printing the pathways on the supporting board prevent the implementation of certain inductors, particularly when the inductors have very small dimensions.

In a third type of electronic circuit, the inductors are implemented in the form of discrete components placed outside the package containing the chip of the integrated electronic circuit. These discrete components are connected to the chip by wires through the package. However, such circuits with discrete components are expensive because of the cost of the discrete components and particularly of their assembly with the circuit chip. In addition, the wires connecting the discrete components present high parasitic resistances and high induction losses.

### BRIEF SUMMARY

One aspect of the present disclosure is to provide a new type of electronic circuit with inductors that does not present the disadvantages listed above.

To this end, an integrated electronic circuit chip is provided that includes:
a substrate,
a layering of metallization levels formed above a surface of the substrate in a direction perpendicular to this surface, with each level having electrical connections,
a protective layer for the metallization levels that is positioned on top of a last one of the metallization levels relative to the substrate, and
an inductor.

Ideally, the inductor is placed above the protective layer, such that a thickness of the inductor in the direction perpendicular to the surface of the substrate extends from and beyond an upper surface of the protective layer on a side opposite the substrate.

In this manner, the inductor belongs to the chip without being placed in one of the chip's metallization levels containing electrical connections such as conductive pathways or vias. The inductor then can have a significant thickness, such that the inductor can have a low or extremely low electrical resistance. For example, the inductor thickness can exceed 20 μm (micrometers) in the direction perpendicular to the substrate, and in one embodiment the thickness is in the range of 50 μm to 60 μm. Under these conditions, the inductor can have a particularly high quality factor, exceeding 30 in particular. Such a quality factor is compatible with many applications of the circuit chip, particularly applications in the radiofrequency domain.

Another advantage results from the placement of the inductor outside the metallization levels that form the pathways and vias of the circuit chip. These metallization levels generally present complex patterns of pathways and vias, which prevent or complicate the insertion of an inductor. The present disclosure therefore permits integrating the inductor into the chip without adding an additional metallization level or increasing the dimensions of the substrate.

Yet another advantage of the disclosure results from moving the inductor further away from the semiconductor substrate and from the electronic components that are placed on the surface of the substrate, such as transistors. In fact, the inductor is separated from these components by the dielectrics of the interconnection levels, as well as by the protective layer. The inductor therefore has reduced parasitic interactions with these components situated on the substrate surface, achieving low values even if significant electric current is traveling through the inductor. The operation of the electronic circuit is thus improved.

Given that the inductor is placed above the protective layer, a pathway or track that electrically connects one of the ends of the inductor can easily be implemented in the last metallization level of the chip. In particular, when the inductor is spiral in shape, the central end of the spiral can be connected in this manner.

Lastly, as the inductor is implemented in the form of an integrated component of the electronic circuit chip, its manufacturing cost is very low. In addition, the realization of the inductor can be combined with the realization of the connections intended to connect the chip to a supporting board using flip-chip technology. The realization of the inductor then does not require the addition of supplemental steps to the chip realization process, only the adaptation of certain masks already used to realize the connections between the chip and the supporting board is required. Thus, according to the present disclosure, the electronic circuit chip additionally includes at least one chip connection pad that extends beyond the protective layer. This chip connection pad itself includes a metal body that extends in a direction perpendicular to the substrate surface, to a height above the upper surface of the protective layer that is at least equal to the thickness of the inductor. Such a pad is adapted to connect the circuit chip to the supporting board via a solder bump, with this solder bump placed between one end of the metal body and a connection pad that is on the supporting board.

Within the context of the present disclosure, the chip connection pad that is provided for electrically connecting the chip to the supporting board has a shape that is appropriate for a solder ball, also called a solder bump, being placed on top of it. In particular, the metal body preferably has an inner volume that is full of material. It has an upper surface of almost circular and flat shape, such as a disk, without any hole or significant depression at a center of this upper surface. In this way, the solder ball can be formed on top of the pad with an almost regular or spherical shape. This ensures that the electrical connection is reliable and easy to complete.

The disclosure also provides a process for implementing an integrated electronic circuit chip, which includes the following steps:

(1) realizing a layering of metallization levels above a surface of a substrate of the circuit chip, the levels being superimposed or stacked in a direction perpendicular to the surface of the substrate and each level comprising electrical connections,

(2) realizing a protective layer for the metallization levels above one of the last of the metallization levels relative to the substrate, and

(3) above the protective layer, realizing an inductor such that it presents or has a thickness, in the direction perpendicular to the surface of the substrate, that extends from and beyond an upper surface of the passivation layer on a side opposite the substrate.

The inductor is realized at the same time as at least one metal body of a connection pad of the circuit chip, with this pad being adapted for connecting the circuit chip to a supporting board via a solder bump placed between one end of the metal body and a board connection pad on the supporting board.

The chip connection pad may be located at a distance apart from the inductor in a plane parallel to the substrate surface.

The inductor and the metal body of the connection pad can be implemented in step (3) using variable deposition processes such as screen printing. Alternatively, when the inductor is implemented by electroplating, step (3) includes the following sub-steps:

(3-1) depositing an electrically conductive layer above the protective layer,

(3-2) forming on the conductive layer a mask that has an two openings corresponding respectively to the inductor and the metal body of the connection pad,

(3-3) forming the inductor and the metal body of the connection pad by electroplating a conductive material in the mask openings, starting from the conductive layer,

(3-4) removing the mask, and

(3-5) removing the portions of the conductive layer not covered by the inductor or the metal body of the connection pad.

The conductive layer formed in step (3-1) serves to carry the electrical current necessary for the electrochemical reaction that produces the material of the inductor and the metal body.

The process can additionally include, between steps (2) and (3), the formation of an intermediate layer of material on and in contact with the protective layer. The inductor and possibly the metal body of the connection pad is then implemented in step (3) directly on this intermediate layer. Such an intermediate layer can improve the adhesion of the inductor and the metal body of the connection pad onto the protective layer. When this intermediate layer is electrically conducting, the portions that are not covered by the inductor or the metal body of the connection pad are removed after step (3).

The process can additionally include the following steps:

(4) depositing an additional solder bump onto a segment of the inductor, and

(5) connecting the circuit chip to a supporting board by soldering, via the additional solder bump, the segment of the inductor to a board connection pad that is on the supporting board.

In this manner, the circuit chip is connected to a supporting board via the inductor. In this case, the circuit chip additionally includes at least the solder bump that is placed on the inductor segment, on a side opposite the substrate, and that is adapted to connect the inductor segment electrically to the board connection pad.

When the chip is to be connected to the supporting board both by the pad located apart from the inductor and by a segment of the inductor, soldering beads can be simultaneously placed in step (4) on the inductor segment and on the metal body of the chip connection pad. The inductor segment and the metal body are then soldered simultaneously in step (5) to the corresponding board connection pads.

The disclosure also proposes an electronic circuit assembly that includes:
an integrated electronic circuit chip as described above, and
a chip support to which this integrated electronic circuit chip is connected.

In a preferred circuit assembly method, the chip and the chip support are oriented such that the inductor is located between the chip substrate and the chip support and are connected to each other by solder bumps. Such an assembly method corresponds to the flip-chip process, and a solder bump process can be used.

In accordance with another aspect of the present disclosure, a system on chip is provided that includes a substrate having a first surface; a plurality of metallization layers formed over the first surface of the substrate, each metallization layer having at least one electrically connective metal path; at least one passivation layer formed over the plurality of metallization layers; and an inductor formed only on top of the at least one passivation layer to extend from the passivation layer in a direction away from the substrate.

In accordance with another aspect of the foregoing embodiment, the system on chip includes electrical connections coupled to the at least one electrically conductive metal path and to the inductor; a supporting board having at least one electrical connection pad; and at least one solder bump electrically coupling the electrical connection pad to at least one of the electrical connections.

In accordance with yet another aspect of the foregoing embodiment, the system on chip includes an electrically conductive layer formed between the inductor and the passivation layer and in electrical contact with the inductor and at least one of the electrically conductive pathways; and an intermediate layer formed between the passivation layer and the electrically conductive layer and formed to improve adhesion of the electrically conductive layer to the passivation layer.

In accordance with another embodiment of the disclosure, a method of forming a system on a chip is provided, the method including providing a substrate having a first surface; forming a plurality of metallization layers over the first surface of the substrate, each metallization layer formed to have at least one electrically connective metal path; forming at least one passivation layer over the plurality of metallization layers; and forming an inductor only on top of the at least one passivation layer to extend from the passivation layer in a direction away from the substrate.

In accordance with another aspect of the foregoing embodiment, the method includes forming electrical connections that are coupled to the at least one electrically conductive metal path and to the inductor; providing a supporting board having at least one electrical connection pad; and forming at least one solder bump on at least one of the electrical connections and attaching the solder bump to the electrical connection pad on the supporting board.

In accordance with yet a further aspect of the foregoing embodiment, the method includes forming an electrically conductive layer on the passivation layer before forming the inductor, with the electrically conductive layer formed to be in electrical contact with at least one of the electrically conductive pathways; and forming an intermediate layer on the passivation layer before forming the electrically conductive layer, the intermediate layer formed to improve adhesion of the subsequently formed electrically conductive layer to the passivation layer.

### BRIEF DESCRIPTION OF THE SEVERAL VIEWS OF THE DRAWINGS

Other features and advantages of the disclosure will become clear in the following description of a non-limiting example, with references to the attached drawings where:

FIGS. 1 to 6 illustrate steps in the realization of an integrated electronic circuit chip of the present disclosure, and

FIG. 7 illustrates a circuit assembly that comprises a chip of FIGS. 1 to 6.

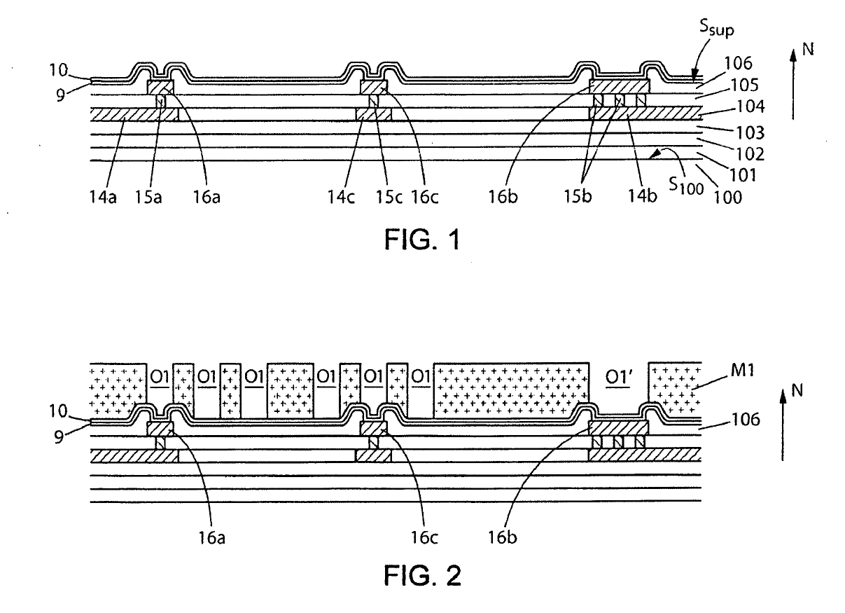

For clarity, the dimensions of the various elements represented in these figures are not proportional to the actual sizes or size ratios. FIGS. 1, 2, 3a and 4 to 7 are cross-section views of an integrated electronic circuit chip implemented from an essentially flat substrate, in a plane perpendicular to the surface of the substrate. N indicates a direction perpendicular to the surface of the substrate, oriented towards the exterior of the substrate. In the rest of this document, the terms “on”, “under”, “below” and “above” are used relative to this orientation for the circuit chip. The same references correspond to the same elements in all figures.

### DETAILED DESCRIPTION

The basic steps of the electronic circuit fabrication process that would be known to a person skilled in the art are not described in detail. Only a succession of basic steps for realizing an electronic circuit of the disclosure are described.

As shown in FIG. 1, during the fabrication process, an integrated electronic circuit chip includes a substrate 100 of semiconductor material, a pre-metallization layer 101, and several metallization levels 102-105. The pre-metallization layer 101 and the metallization levels 102-105 are superimposed onto the surface of the substrate 100, labeled S100. There can be any number of metallization levels, depending on the complexity of the electrical connections of the circuit in particular. In a known manner, each metallization level comprises a layer of electrically insulating material, for example silicon dioxide (SiO₂), in which are engraved or formed one or more electrical connection paths or patterns and possibly patterns of integrated electronic components. For each level, these patterns are then filled with metal, for example copper when the Damascene process or its dual-Damascene variant is used, in order to form the connections and the components placed in the level. In the figures, only three conductive pathways 14a-1 4c are represented in level 104, and a few vias 15a-1 5c in level 105, but it is understood that each of the levels 102-105 contains a large number of pathways and vias.

Conductive portions 16a, 16b and 16c are then realized, in copper for example, above the level 105. These portions are to ensure an electrical contact between elements of the circuit situated above the level 105 and other elements of the chip. They can be connected to one or more vias 15-15c of the level 105.

The circuit is then covered with a protective layer 106, called the passivation layer. In particular, the layer 106 can be of silicon nitride or Phosphorus-Silicon Glass, commonly called PSG. The upper surface of the layer 106, labeled S_{SUP}, corresponds to the upper surface of the chip, which is situated on a side of the chip or a side of the protective layer 106 opposite the substrate 100. Openings are then made in the protective layer 106 to expose the conductive portions 16a-16c. A lithography mask can be used in a known manner to define these openings.

An intermediate layer 9, which can be based on titanium (Ti), then a conductive layer for supplying power 10, which can be based on copper (Cu), are successively deposited onto the circuit. The layers 9 and 10 can have thicknesses in direction N of about 20 nm (nanometers) and 200 nm respectively. The layer 9 serves to increase the adhesion of the layer 10 onto the protective layer 106.

Next a first resin mask M1 is formed on the circuit (FIG. 2) by lithography. The mask M1 can have a thickness in direction N of between 40 and 100 μm (micrometers). It has openings that expose the power supply layer 10. These openings can correspond to different elements of the electronic circuit. In particular, an opening O1, which can be in the shape of a spiral, corresponds to the inductor, and an opening O1′ can correspond to a connection pad body for connecting the chip to a supporting board at a later time. In FIG. 2, the opening O1 appears at several locations in the mask M1, corresponding to the intersections of the inductor spiral with the cross-sectional plane of the figure. It is possible for the opening O1 to be locally superimposed onto a conductive portion 16a, 16c.

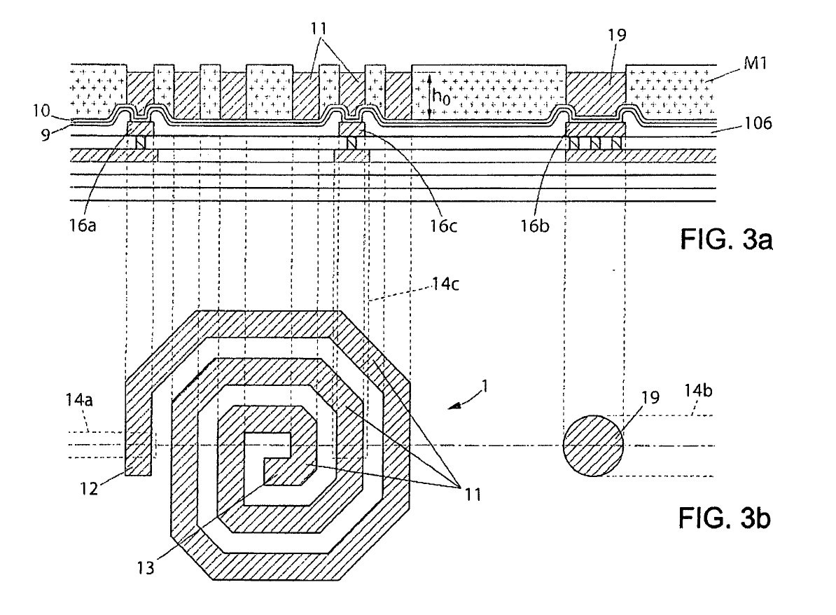

A conductive material, which can be copper (Cu), is then placed in the openings O1 and O1′ by electroplating. To achieve this, the chip can be immersed in a solution containing metal ions. An electric current is then introduced into the conductive layer 10 and travels to an electrode external to the chip, which is also immersed in the solution. Such electroplating is a rapid means of obtaining conductive portions 11 and 19 (FIG. 3a), which can be thick, inside openings O1 and O1′ respectively. For example, the thickness ho of portions 11 and 19 can be between a few micrometers and 100 μm, in particular greater than 20 μm, in the direction N. In particular, ho can be in the range of approximately 50 μm to 60 μm, and in another embodiment is substantially equal to 50 μm. FIG. 3b is a top view of the circuit corresponding to FIG. 3a. It illustrates the spiral of the portion 11, which can comprise three turns. The two ends of the spiral are labeled 12 and 13. These are respectively located on the periphery and inside the spiral. For this reason, the ends 12 and 13 are respectively called the external end and the central end of the inductor. FIG. 3b also shows the pathways 14a-14c as dotted lines across the mask M1, and the layers 10, 9, and 106, as well as the metallization level 105.

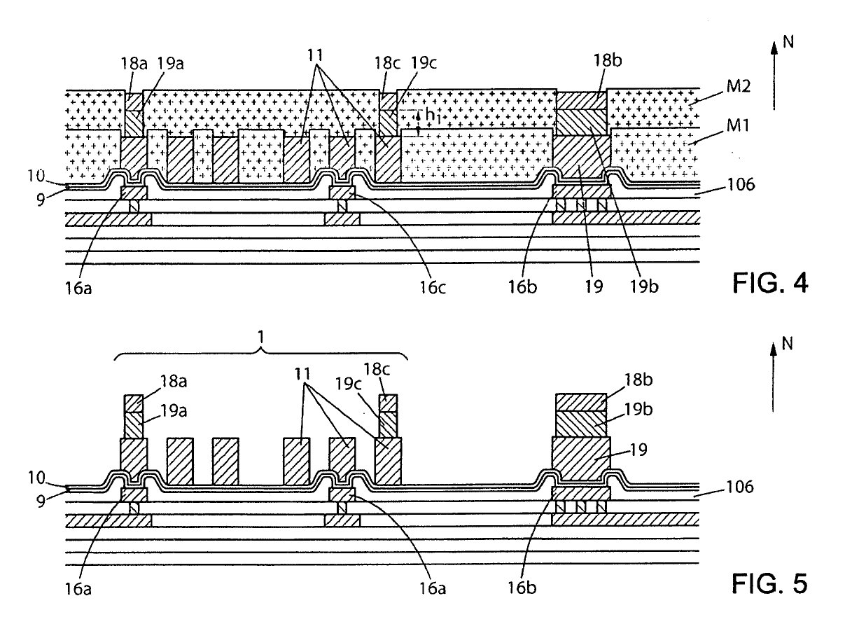

Solder beads, for example bumps, can then be formed above the portion 19 as well as possibly above certain segments of the portion 11. Such solder bumps can be formed on one or both ends of the portion 11 in order to connect the inductor directly to a chip support (labeled 300 in FIG. 7). It is also possible for a continuous line of solder to be formed on all or part of the portion 11, to further decrease the electrical resistance of the portion. One of the techniques commonly used to form these solder beads is screen printing. To do this, a second resin lithography mask M2 (FIG. 4) is formed on the circuit, with openings positioned above the portion 19 and above the concerned segments of the portion 11. It is understood that the mask M2 may have no openings above the portion 11, when the inductor is not to be connected to the chip support at a later time.

Optionally, the portion 19 as well as the segments of the portion 11 which are left exposed by the mask M2 can be extended in the direction N. A second step of electroplating is then performed, for example using a process identical to the one described for the realization of portions 11 and 19. Conductive extension portions 19a, 19b, and 19c are then realized on the exposed segments of the portion 11 and on the portion 19. Advantageously, the portions 19a, 19b and 19c do not fill the openings of the mask M2 up to the upper surface of the mask, such that the upper parts of these openings can still be used to form the solder bumps. For example, the extension portions 19a, 19b, and 19c extend to a height h₁ of about 20 μm or more in the direction N. Because of these extension portions, the inductor will be farther from the supporting board in the final circuit assembly, meaning once the chip is assembled with the supporting board by the flip-chip method. In addition, at an equal distance separating the chip and the supporting board, the extension portions 19a, 19b, and 19c, when they are of copper, allow reducing the electrical resistance of the chip connections to the supporting board.

A solder paste is then screen printed onto the mask M2, such that it completely fills in the openings of the mask M2. Solder portions 18a, 18b, and 18c are then formed above segments of the pathway 11 and above the portion 19. The solder portions 18a, 18b, and 18c can be an alloy of lead and tin, or an alloy of copper, silver, and tin when the use of lead is not desirable. In an alternative to the screen printing process, the solder portions 18a, 18b, and 18c can be formed by electroplating, again by using the power supply layer 10.

The mask M2 is removed, then the mask M1. The chip configuration illustrated in FIG. 5 is then obtained.

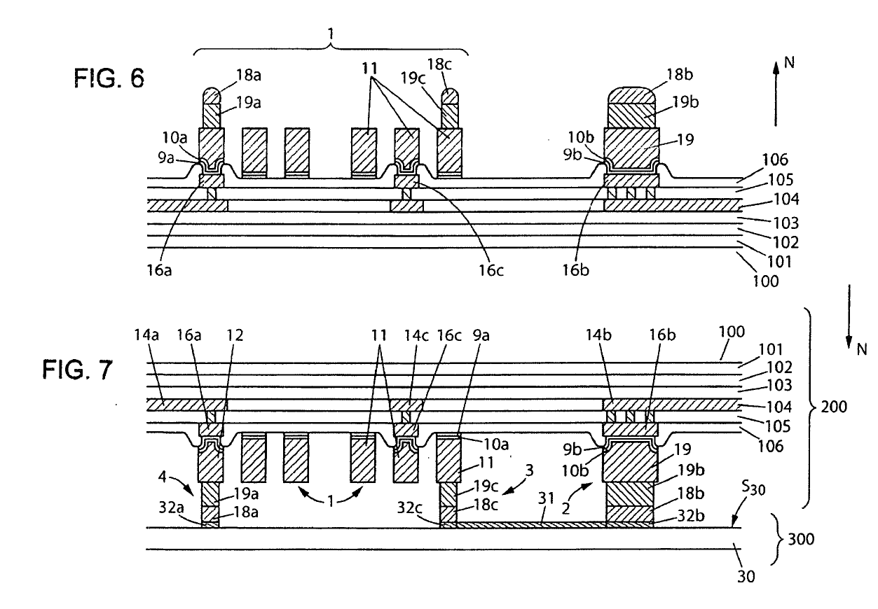

The layer 10 is then etched, then the layer 9, aside from the portions of these layers which are covered by the portions 11 and 19. Such etching can be achieved by immersing the chip in an acid and possibly oxidizing solution. Such a wet etching process is assumed to be known. Due to the fact that the thicknesses of layers 9 and 10 are much smaller than the dimensions of the portions 11, 19, and 19a-19c, the latter are not significantly modified by this etching step. The turns of the portion 11 are thus electrically insulated in the radial direction of the spiral, and insulated from the portion 19 (FIG. 6).

The spiral portion 11 and the remaining portions of layers 9 and 10, respectively labeled 9a and 10a for those portions situated under the portion 11, form the inductor 1. When a portion 16a, 16c is situated under a segment of the inductor 1, the portions 9a and 10a ensure an electrical contact between that inductor segment and that portion 16a, 16c. In the same manner, the remaining portions 9b and 10b of layers 9 and 10 which are situated under the portion 19 electrically connect the portion 19 to the portion 16b.

A heating of the circuit chip, called “reflow”, is then performed in order to improve the contact of portions 18a-18c with portions 19a-19c respectively. During this heating, the portions 18a-18c become rounded at their upper ends and thus form solder beads.

FIG. 7 represents a circuit assembly wherein the above chip, labeled 200, is assembled with a supporting board, labeled 300. The supporting board comprises a base support 30 and board connection pads 32a-32c. The base support 30 is commonly called the laminate, and is of fiber-reinforced resin. The board connection pads 32a-32c are arranged on a surface S₃₀ of the support 30, respectively facing portions 19a-19c when the surfaces S₃₀ and S₁₀₀ of the support 30 and the chip 200 are turned towards each other. The chip 200 is then turned upside down above the chip supporting board 300 using the flip-chip technique as indicated by the direction N which is again indicated in FIG. 7. The pads 32a-32c are simultaneously soldered to the portions 19a-19c via the respective solder bumps 18a-18c.

A connection 2 is thus established, connecting the pathway 14b of the chip 200 to the board connection pad 32b via the portions 16b, 19, and 19b. Connections 3 and 4 connect the inductor 1 to the board connection pads 32a and 32c. It is also possible for the supporting board 30 to comprise conductive pathways printed on the surface S₃₀, for example in copper, which connect some of the board connection pads. As an illustration, the represented pathway 31 connects the pads 32b and 32c, such that a peripheral segment of the inductor 1 is electrically connected to the pathway 14b of the chip metallization level 104 via the supporting board 300. Another turn of the inductor 1 is connected to the pathway 14c in a manner internal to the chip 200 by means of the portion 16c. Lastly, the end 12 of the inductor 1 is connected to the pathway 14a by means of the portion 16a, also in a manner internal to the chip 200.

It is understood that the disclosure, which concerns the deposition of the inductor 1 onto the upper surface of the chip 2, can be implemented independently of the realization of the connections 2-4. In addition, many modifications can be introduced to the embodiment of the invention detailed above. In particular, the following modifications can be made:
the segment of the inductor 1 that bears a solder bump 18c and by which the chip 200 is connected to the supporting board 300 can be the central end of the inductor 1, which is situated within the interior of the spiral shape of the inductor, in a plane parallel to the surface S₁₀₀. In this manner, the central end 13 of the inductor 1 can easily be connected to another element of the chip 200, by means of a printed pathway on the support 30,
the portion 11 of the inductor 1 can be formed by screen printing above the protective layer 106 rather than by electroplating. It is then not necessary to create the layer 10 which is intended to supply the electricity for the electroplating process, or the layer 9 which has the function of improving the adhesion of the layer 10,
the portion 11 of the inductor 1 can be of an electrically conductive material other than copper. Copper is preferred, however, because of its low electrical resistance and its high resistance to the electromigration phenomenon,
the inductor 1 can have a form different than the described spiral, on the upper surface of the chip 200, and
the realization of the extension portions 19a-19c is not indispensable. However, these portions do enable an advantageous reduction in the parasitic interactions between the inductor 1 and the pathways printed on the surface S₃₀ of the supporting board 300.

Lastly, the invention can be applied to the realization of integrated electronic circuit chips in which the inductor is part of the complex components of the circuits, such as voltage transformers, phase converters, voltage converters for producing DC voltage, etc.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated electronic circuit chip, comprising:
a substrate;
a layering of metallization levels superimposed on top of a substrate surface in a direction perpendicular to said surface, with each level comprising electrical connections;
a protective layer for the metallization levels, deposited on top of a last one of the metallization levels relative to the substrate; and
an inductor arranged above the protective layer, with a thickness of said inductor extending from and beyond an upper surface of the protective layer in a direction perpendicular to the surface of the substrate, on a side of the protective layer opposite the substrate,
wherein said integrated electronic circuit chip further comprises at least a chip connection pad, with said chip connection pad comprising a metal body extending in the direction perpendicular to the surface of the substrate to a height beyond the upper surface of the protective layer at least equal to the thickness of the inductor, and adapted for connecting the circuit chip to a supporting board via a solder bump placed between one end of the metal body and a board connection pad on the supporting board.

2. The circuit chip of claim 1 wherein the thickness of the inductor is greater than 20 μm.

3. The circuit chip of claim 2, wherein the thickness of the inductor is in the range of 50 μm to 60 μm.

4. The circuit chip of claim 1, comprising a portion of intermediate material placed between the protective layer and the inductor, in contact with said protective layer and with said inductor.

5. The circuit chip of claim 1, wherein the chip connection pad is located at a distance apart from the inductor in a plane parallel to the substrate surface.

6. The circuit chip of claim 1, comprising at least one other solder bump placed on a segment of the inductor on a side opposite the substrate and adapted to connect electrically said inductor segment to another board connection pad on supporting board.

7. The circuit chip of claim 5 wherein the inductor segment bearing the other solder bump is an end of said inductor, with said end located inside or outside at least one turn of the inductor in a plane parallel to the surface of the substrate.

8. A process for implementing an integrated electronic circuit chip, comprising the following steps:
(1) realizing a layering of metallization levels above a surface of a substrate of said circuit chip, with said levels being superimposed in a direction perpendicular to said surface and each comprising electrical connections;
(2) realizing a protective layer for the metallization levels, above one of the last of the metallization levels relative to the substrate; and
(3) above the protective layer, realizing an inductor such that said inductor presents, in the direction perpendicular to the surface of the substrate, a thickness extending from and beyond an upper surface of the passivation layer on a side opposite the substrate,
wherein the inductor is realized at the same time as at least one metal body of a connection pad of the circuit chip, with said pad being adapted for connecting said circuit chip to a supporting board via a solder bump placed between one end of the metal body and a board connection pad on the supporting board.

9. The process of claim 7 wherein the chip connection pad is located a distance apart from the inductor in a plane parallel to the substrate surface.

10. The process of claim 8 wherein the step (3) comprises the following sub-steps:
(3-1) depositing an electrically conductive layer above the protective layer;
(3-2) forming, on the conductive layer, a mask that has two openings corresponding respectively to the inductor and to the metal body of the connection pad;
(3-3) forming the inductor and the metal body of the connection pad by electroplating a conductive material within the openings of the mask, starting from the conductive layer;
(3-4) removing the mask; and
(3-5) removing the portions of the conductive layer not covered by the inductor or the metal body of the connection pad.

11. The process of claim 8 wherein the inductor is formed in step (3) such that it has a thickness greater than 20 μm in the direction perpendicular to the surface of the substrate.

12. The process of claim 11, wherein the inductor thickness is in the range of 50 μm to 60 μm.

13. The process of claim 8, additionally comprising the following step:
between steps (2) and (3), forming a layer of intermediate material on top of and in contact with the protective layer, with the inductor realized directly on said intermediate layer in step (3).

14. The process of claim 8, additionally comprising the additional steps:
(4) depositing another solder bump on a segment of the inductor; and
(5) connecting the circuit chip to the supporting board by soldering, via the another solder bump, said inductor segment to another board connection pad on the supporting board.

15. The process of claim 14 wherein the inductor segment bearing the another solder bump is an end of said inductor, with said end located inside or outside at least one turn of the inductor in a plane parallel to the surface of the substrate.

16. The process of claim 14 wherein solder bumps are simultaneously deposited in step (4) onto the inductor segment and onto the metal body of the chip connection pad, and wherein the inductor segment and the metal body are soldered simultaneously in step (5) to the corresponding board connection pads.

17. An electronic circuit assembly, comprising:
an integrated electronic circuit chip according to claim 1; and
a chip support to which said integrated electronic circuit chip is connected.

18. The circuit assembly of claim 17 wherein the chip and the chip support are oriented such that the inductor is positioned between the substrate of the chip and the chip support, and wherein the chip and the chip support are connected to each other by solder bumps.

19. A system on chip, comprising:
a substrate having a first surface;
a plurality of metallization layers formed over the first surface of the substrate, each metallization layer comprising at least one electrically connective metal path;
at least one passivation layer formed over the plurality of metallization layers; and
an inductor formed only on top of the at least one passivation layer to extend from the passivation layer in a direction away from the substrate.

20. The system on chip of claim 19, comprising:
electrical connections coupled to the at least one electrically conductive metal path and to the inductor;
a supporting board having at least one electrical connection pad; and
at least one solder bump electrically coupling the electrical connection pad to at least one of the electrical connections.

21. The system of claim 19, comprising:
an electrically conductive layer formed between the inductor and the passivation layer and in electrical contact with the inductor and at least one of the electrically conductive pathways; and
an intermediate layer formed between the passivation layer and the electrically conductive layer and formed to improve adhesion of the electrically conductive layer to the passivation layer.

22. A method of forming a system on chip, comprising:
providing a substrate having a first surface;
forming a plurality of metallization layers over the first surface of the substrate, each metallization layer formed to have at least one electrically connective metal path;
forming at least one passivation layer over the plurality of metallization layers; and
forming an inductor only on top of the at least one passivation layer to extend from the passivation layer in a direction away from the substrate.

23. The method of claim 22, comprising:
forming electrical connections that are coupled to the at least one electrically conductive metal path and to the inductor;
providing a supporting board having at least one electrical connection pad; and
forming at least one solder bump on at least one of the electrical connections and attaching the solder bump to the electrical connection pad on the supporting board.

24. The method of claim 22, comprising:
forming an electrically conductive layer on the passivation layer before forming the inductor, the electrically conductive layer formed to be in electrical contact with at least one of the electrically conductive pathways; and
forming an intermediate layer on the passivation layer before forming the electrically conductive layer, the intermediate layer formed to improve adhesion of the subsequently formed electrically conductive layer to the passivation layer.
